(19) United States
(12) Patent Application Publication
(10) Pub. No.: US 2013/0126892 A1
(43) Pub. Date: May 23, 2013

(54) P-Type Amorphous GaNAs Alloy as Low Resistant Ohmic Contact to P-Type Group III-Nitride Semiconductors

(71) Applicants: Kin Man Yu, Lafayette, CA (US); Wladyslaw Walukiewicz, Kensington, CA (US); Alejandro X. Levander, Berkeley, CA (US); Sergei V. Novikov, Nottingham (GB); C. Thomas Foxon, Nottingham (GB)

(72) Inventors: Kin Man Yu, Lafayette, CA (US); Wladyslaw Walukiewicz, Kensington, CA (US); Alejandro X. Levander, Berkeley, CA (US); Sergei V. Novikov, Nottingham (GB); C. Thomas Foxon, Nottingham (GB)

(73) Assignee: THE REGENTS OF THE UNIVERSITY OF CALIFORNIA, Oakland, CA (US)

(21) Appl. No.: 13/475,420

(22) Filed: May 18, 2012

Related U.S. Application Data
(60) Provisional application No. 61/488,036, filed on May 19, 2011.

(51) Int. Cl. H01L 29/20; H01L 21/04

(52) U.S. Cl. CPC H01L 29/2003; H01L 21/04
USPC 257/76; 438/513; 252/512; 428/220

(57) ABSTRACT

A new composition of matter is described, amorphous GaN₁₋ₓAsₓ:Mg, wherein 0<x<1, and more preferably 0.1<x<0.8, which amorphous material is of low resistivity, and when formed as a thin, heavily doped film may be used as a low resistant p-type ohmic contact layer for a p-type group III-nitride layer in such applications as photovoltaic cells. The layer may be applied either as a conformal film or a patterned layer. In one embodiment, as a lightly doped but thicker layer, the amorphous GaN₁₋ₓAsₓ:Mg film can itself be used as an absorber layer in PV applications. Also described herein is a novel, low temperature method for the formation of the heavily doped amorphous GaN₁₋ₓAsₓ:Mg compositions of the invention in which the doping is achieved during film formation according to MBE methods.

### CROSS REFERENCE TO RELATED APPLICATIONS

This US application claims priority to U.S. Provisional Application Ser. No. 61/488,036 filed May 19, 2011, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-AC02-05CH1231 between the U.S. Department of Energy and the Regents of the University of California for the management and operation of the Lawrence Berkeley National Laboratory. The government has certain rights in this invention.

### BACKGROUND OF THE INVENTION

1. Field of the Invention

This invention relates generally to a novel composition of matter comprising an amorphous, p-doped GaNAs, and more particularly to an amorphous GaNAs film doped with Mg, and a method of preparation thereof, which film can serve as a low resistance ohmic contact layer in such applications as solar cells, light emitting diodes, laser diodes, and the like.

2. Brief Description of the Related Art

Semiconductor devices (e.g. light emitting diodes, laser diodes, solar cells and high power electronic devices) made from Group III metal-nitride materials such as gallium nitride (GaN), indium gallium nitride (InGaN), aluminum gallium nitride (AlGaN) or indium aluminum nitride (InAlN) have been widely investigated, and commonly are connected to electrical contacts through which electric current received via a bonding wire can be distributed across the surface of the semiconductor material for conduction through the bulk or thin surface layer. Such contacts are commonly referred to as ohmic contacts.

To minimize heat generation and reduce power consumption in the semiconductor device, the electrical resistance of the electrical contact, and the voltage drop across the contact needs to be minimized. In general the properties of the contacts are determined by the nature of the metal/semiconductor interface. In the case of an ideal, unpinned interface ohmic low resistivity to p-type nitride semiconductor, required is a metal with work function higher than 6 eV. However, even platinum with the highest work function of 5.4 eV does not satisfy this conduction requirement. In fact the majority of the metal semiconductor contacts are far from being ideal, in most instances, the Fermi energy at the metal/semiconductor interface is pinned, resulting in the formation of a depletion region and barrier impeding charge transport across the interface.

To address this problem, the resistivity of the contact can be reduced by heavy doping of the semiconductor region adjacent to the contact. The doping reduces the thickness of the barrier so that carriers can pass through by quantum mechanical tunneling and thus lowering the contact resistance. The main problem with p-type group III-nitrides, however, is that the doping (larger than 10¹⁹/cm³) required for low resistance contacts simply cannot be achieved. Consequently reliable low resistance ohmic contacts on p-type group III-nitrides are difficult to realize.

The current state of the art non-alloyed ohmic contacts of p-type GaN utilize either Ni—Au alloys, multi component metallization, e.g. Ni—Ag—Pt, Ni—Au—Zn, Pd—Ni—Au, etc. Specific contact resistance as low as 10⁻⁶ ohm-cm² has been reported, but values in the range of 10⁻² ohm-cm² to 10⁻³ ohm-cm² are more typical. However, due to the complexity of the metallization scheme, good ohmic contacts to p-type GaN are not always reproducible, even using identical procedures. The issue is especially important for high current devices such as laser diodes or concentrator solar cells in which the overall performance is critically dependent on the availability of very low resistance ohmic contacts.

### SUMMARY OF THE INVENTION

This invention enables the fabrication of reproducible low resistance ohmic contact to, for example, p-type InGaN using an amorphous GaNAs layer heavily doped with magnesium (Mg) according to the formula GaN₁₋ₓAsₓ:Mg, wherein the mole faction x is between 0 and 1, more commonly between 0 and 0.8, and more preferably between 0.1 and 0.8. The Mg dopant range can vary from 3×10²⁰ to 3×10²¹ atoms/cm³, and more narrowly from 6×10²⁰ to 1×10²¹ atoms/cm³. Since the GaNAs:Mg layer is both thin, and amorphous, no lattice matching with an underlying semiconductor layer such as CaN is required.

This invention provides an entirely new approach to the problem of low resistivity ohmic contacts to p-type group III-nitride semiconductors. It is to be appreciated that GaNAs is not the only alloy that can be used with Mg in this application. According to the prediction of the band anticrossing (BAC) model [W. Walukiewicz, W. Shan, K. M. Yu. J. W. Ager III, E. E. Haller, I. Miotlowski, M. J. Seong, H. Alawadhi, and A. K. Ramdas, Phys. Rev, Lett. 85, 1552 (2000)], similar effects can be expected for GaN alloyed with GaP, GaSb and GaBi to form GaNP, GaNSb, and GaNBi alloys respectively. Moreover, the application of this material as an ohmic contact layer is not limited to use with gallium nitride alloys. It can be used in a similar fashion as a p-type ohmic contact with such films as, for example, comprised of indium gallium nitride (InGaN), aluminum gallium nitride (AlGaN) and aluminum indium gallium nitride (AlInGaN) alloys.

In an embodiment, the amorphous GaNAs:Mg material can be formed by plasma assisted molecular beam epitaxy methods (PAMBE) in which Mg (a p-type dopant) is added as an additional component, the amount being added controlled by regulation of the Mg partial pressure during the film formation process. Also, important to the obtaining of the amorphous form of the GaNAs film is the amount of As incorporated into the film material, the amount a function of MBE process temperature, with temperatures below 400° C., and as low as for example about 100° C., leading to greater As incorporation. For a further description of the MBE process, please see our earlier papers entitled Molecular beam epitaxy of crystalline and amorphous GaN layers with high As content, S. V. Novikov, et al., Journal of Crystal Growth, 311 (2009) 3417-3422, Highly Mismatched GaN₁₋ₓAsₓ Alloys in the Whole Composition Range, K. M. Yu et al., J. Appl. Phys. 106, 103709 (2009). Therein the use of MBE is described whereby concentrations of arsenic are incorporated into a GaN film over the whole composition range, to produce films of differing optical band gap properties, depending upon the concentration of the As introduced (See page 3421, FIG. 7 of the article). As reported in the article, at higher temperatures (such as ˜600° C.), and lower As concentrations, the resulting films were crystalline, while at lower temperatures, such as at about 400° C., the films had an amorphous structure with an arsenic content of greater than 20%. In our later article entitled Molecular beam epitaxy of GaNAs alloys with high As content for potential photoanode applications in hydrogen production, S. V. Novikov et al., J. Vac. Sci. Technol B2, C3B12 (May/June 2010), we reported the growth of amorphous films at formation temperatures of ˜100° C. It was observed that by lowering the growth temperatures, it was possible to incorporate more As into the GaN film by increasing the As₂ flux. We reported films with high As content, where 0.1<x<0.75 were amorphous.

As an ohmic contact layer, it is best to keep the GaNAs:Mg layer quite thin, such as in the range of between 5 and 50 nm, and more preferably <20 nm. Further, and by way of example, when the heavily p-type doped GaNAs layer is inserted between a p-GaN layer and a high work function metal (such as platinum), the large barrier (˜2 eV) can be reduced to <1 eV between the GaNAs and the GaN, thus drastically reducing the resistance of the device. In the case of an InGaN—Si hybrid type solar cell, using the highly p-type GaNAs layer as an ohmic contact interlayer between the metal contact can essentially eliminate the ˜1.1 eV energy barrier.

In an embodiment of the invention, it has been found that by increasing the thickness of the layer, such as by increasing process times, the GaNAs alloy can serve as a photovoltaic absorber layer, as well, most preferably when the GaNAs layer is but lightly doped, such as with Mg. In the case where the magnesium doped PV layer comprises the outer layer to which an ohmic contact is to be applied, by continuing the growth of the GaNAs layer for an additional period of time at a higher Mg flux, the ohmic contact layer can be formed, as will hereinafter be explained in the Detailed Description.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic of the MBE apparatus useful for the preparation of the heavily p-doped GaNAs materials of the invention.

FIG. 2 is a time vs. substrate temperature plot of the process for forming the GaNAs:Mg material of the invention.

FIG. 3 is a plot of Mg beam equivalent pressure (BEP) vs. film resistivity according to an embodiment of the invention.

FIG. 4 are calculated energy band diagrams for the case of a p-GaN layer (with hole concentration p˜1×10¹⁸/cm³) both (A) with and (B) without a p⁺-GaN₁₋ₓAsₓ (x=0.1 and p˜1×10²⁰/cm³) top layer.

FIG. 5 are calculated energy band diagrams similar to those of FIG. 4 for the case of a p-In_{0.4}Ga_{0.6}N layer (with hole concentration p˜1×10¹⁸/cm³) both (A) with and (B) without a p⁺-GaN₁₋ₓAsₓ (x=0.1 and p˜1×10²⁰/cm³).

FIG. 6 is a plot of x (reported in mole fractions) vs. E_{g}, the optical band gap energy for the un-doped alloy GaN₁₋ₓAsₓ.

FIG. 7 A is a calculated energy band diagram for another embodiment of the invention in which a thicker p⁺-GaN₁₋ₓAsₓ (with 35% As) layer is matched to a n-ZnO layer (hetero junction). FIG. 7B is a plot of the calculated corresponding PV response under AM 1.5 illumination.

FIG. 8 is a calculated energy band diagram for a GaNAs tandem solar cell with 20% As in the top cell, and 60% As in the bottom cell.

### DETAILED DESCRIPTION

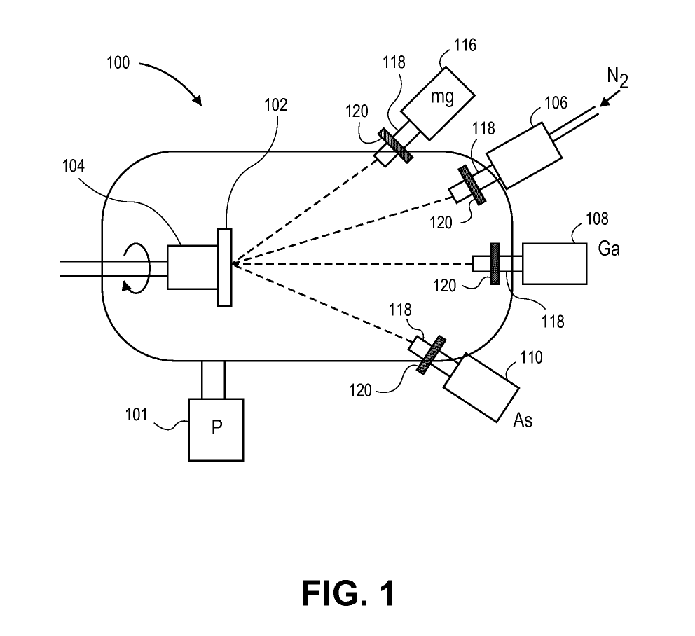

With reference to FIG. 1, a schematic of an MBE apparatus, an MBE chamber 100 is served by one or more turbo and/or cryo pumps 101 capable of achieving the necessary high vacuum conditions (e.g. 10⁻⁹ to 10⁻¹⁰ Torr). A substrate holder or platter 102 is provided upon which the substrate to be coated is placed. Heater 104 is provided below substrate holder 102, which heater is capable of heating the substrate to temperatures in excess of 700° C. A mechanism (not shown) can be used to rotate the heater and holder during the deposition process. The elements to be incorporated into the film alloy are provided in solid form and placed in individual crucibles (not shown) which are located in respective ovens/furnaces 108 and 110. Using heaters in these furnaces capable of heating the solids to temperatures above their sublimation and melting temperatures, the elements are vaporized to gaseous form and introduced into the deposition chamber through portals 118. The relative amounts of material introduction can be controlled by heater temperatures and by shutters 120 which can be opened or closed to permit or prevent the flow of vapor, to thus allow the concentration of a component to either increase or decrease, with concentration regulated according to the gas partial pressure.

The nitrogen gas N₂ must first be cracked to form active and atomic nitrogen before introduction into reaction chamber 100. This is achieved at station 106 in which an rf plasma can be used for this purpose. Control of the nitrogen concentration is achieved by changing the nitrogen gas flow, rf power and by using shutter 120. In the experiments reported below, an HD-25 Oxford Applied research rf activated plasma source was used to provide the active nitrogen. In furnace 116 solid Mg is placed in a crucible and heated to above its sublimation temperature in order to form a vapor for introduction into the MBE chamber, with the partial pressure of the Mg controlled by the temperature of the cell and a shutter 120, much in the same way as with the other components.

The substrate (not shown) which can be sapphire, glass, Pyrex glass, III-V wafer, silicon wafer (with a GaN layer and the like previously formed on the substrate) is affixed to substrate holder 102, where its temperature may be controlled using heating element 104. In the MBE process, the separately heated and introduced elements condense on the substrate, where they react with each other. The term “beam” as used to describe MBE refers to the fact that the evaporated atoms do not interact with each other until they reach the substrate due to the long mean free paths of the atoms. In the instant case the gallium, arsenic and nitrogen alloy to form GaNAs. In this process, the Mg is replaces a fraction of the Ga in the alloy and is thus incorporated as a dopant.

For additional discussion of the MBE process, the reader is referred to the two articles cited above at paragraph 10.

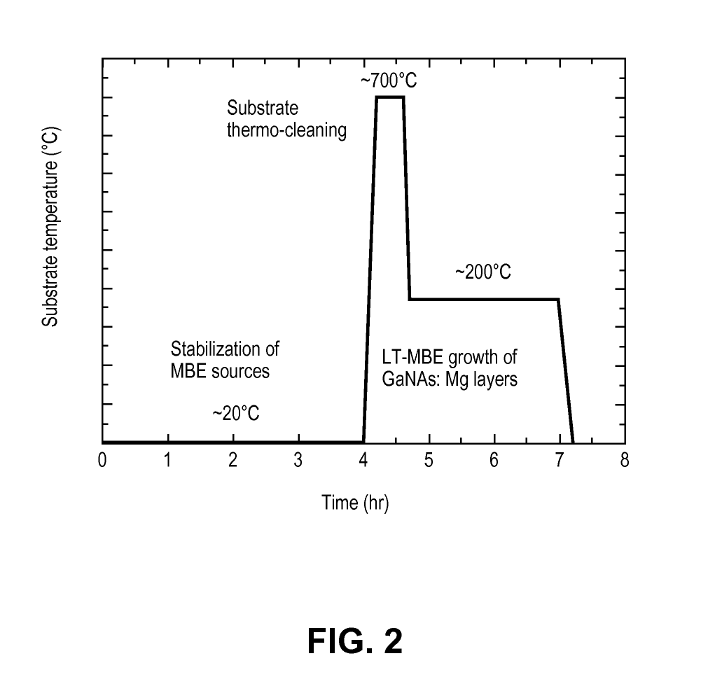

An exemplary process will now be described with reference to FIG. 2. In this process GaNAs:Mg samples were grown on 2″ sapphire (0001) substrates by plasma-assisted MBE (PA-MBE) using a MOD-GENII system. In the first step at time (t)=0, the sapphire substrate is loaded into the MBE growth chamber. The background pressure in the MBE system before the growth is about 10⁻⁹ to 10⁻¹⁰ Torr and is maintained by constant 24/7 pumping using the cryo-pump. At the same t=0 time the heating of the Ga, As and Mg sources to their design temperature is commenced. With the substrate maintained within the chamber at ambient temperature, over the next several hours (e.g. t=3 hours), the Ga, As and Mg sources are each stabilized at the temperatures specific to each required to achieve the designed Ga:N ratio for MBE growth and designed As and Mg concentrations in the layer. The Ga, As and Mg beam fluxes are next determined and the source temperatures adjusted to the design value of the fluxes. Per FIG. 2, this occurs between hours t=3 and t=4. The shutters to these sources are then closed, while the chamber continues to be constantly pumped by the cryo-pump.

With the fluxes having thus been adjusted to design value, at t=4 hours, the temperature of the sapphire substrate is increased to between 600° C. and 800° C. for a period of time (to t=4 hours, 20 min) sufficient to achieve thermal cleaning of the sapphire substrate surface. In the next step, the nitrogen rf plasma source is struck, and flow of nitrogen into the MBE chamber commenced (t=4 hours, 20 min). Thermal cleaning of the substrate is continued in the presence of nitrogen for an additional period of time (to t=4 hours, 40 minutes per FIG. 2). This step complete, the heater is turned down to allow the substrate to cool to the designed growth temperature, such as to between 80° C. to 300° C., and the temperature allowed to stabilize (FIG. 2, t=4 hours, 40 min to 5 hours).

In the next film formation step, simultaneous openings of shutters 120 occurs for all components, Ga, N, As and Mg to start the growth of the GaN₁₋ₓAsₓ:Mg layer (t=5 hours), and growth allowed to continue (with film growth rates of about 0.3 μm per hour) for several more hours until the desired film thickness achieved. In the illustrated example of FIG. 2, the period covers t=5 to t=7 hours at a growth temperature of 200° C. Thickness can be monitored during film growth using reflection high energy electron diffraction. For the films serving as ohmic contacts as described in this invention, film thickness is usually less than 50 nm, and generally will range between 10 and 30 nm. Using this same MBE process to form an absorber PV layer as described later, the deposition process is allowed to continue for an additional period of time until the desired film thickness is reached, such as between about 0.5 to 2 microns.

Once the desired film thicknesses are reached, shutters 120 for the Ga, N, As, and Mg are simultaneously closed to stop the growth of the layer (t=7). At the same time, heating of the substrate is discontinued, and the substrate allowed to cool to room temperature, this step generally taking but a few minutes (from t=7 hr to t=7 hr 15 min). With the film formation process now complete, the nitrogen RF plasma source is shut down along with the Ga, As and Mg containing furnaces, and the substrate, now coated with a GaN₁₋ₓAsₓ:Mg layer, removed from the MBE growth chamber.

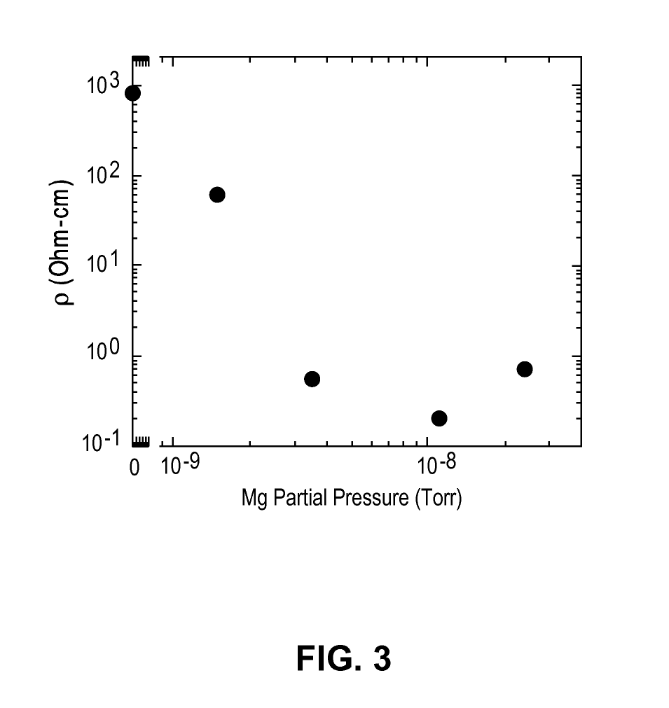

To determine the optimal level of Mg doping for a given film to produce the lowest resistivity for the ohmic contact layer, a series of experiments were performed for a film of the formula GaN_{0.4}As_{0.6} alloy (x=0.6) doped with different amounts of Mg as determined by the Mg beam equivalent pressure, the amount of Mg actually incorporated in the GaNAs film measured by Rutherford backscattering spectrometry. The conductivity type was determined by thermal power measurements and the resistivity of the p-doped film determined by Hall Effect measurements in the Van der Pauw geometry. The results are plotted at FIG. 3. Exemplary of the various settings for some samples are set forth at Table 1, below.

TABLE 1

Sample No.

| | SN-515 | SN-518 | SN-519 |
|---|---|---|---|
| 2″substrate | Sapphire | Sapphire | Sapphire |
| GaN | 7.5 mV | 7.5 mV | 7.5 mV |
| Growth T | | | |
| (mV) | | | |
| Ga (Torr) | ~2.2 10⁻⁷ | ~2.2 10⁻⁷ | ~2.2 10⁻⁷ |
| As (Torr) | ~7.4 10⁻⁶ | ~7.4 10⁻⁶ | ~7.4 10⁻⁶ |
| Mg (Torr) | ~3.5 10⁻⁹ | ~1.1 10⁻⁸ | ~2.4 10⁻⁸ |
| t (hr) | 2 hr | 2 hr | 2 hr |
| Substr. | 10 | 10 | 10 |
| Rotation (rpm) | | | |
| RHEED | amorph | amorph | amorph |
| R | | | |
| centre | ~9 kΩ | ~3 kΩ | ~10 kΩ |
| edge | ~12 kΩ | ~5 kΩ | ~10 kΩ |
| Conductivity | p-type | p-type | p-type |
| type | | | |

All GaNAs:Mg samples were grown on 2″ sapphire substrates by plasma-assisted MBE. The MBE system in which the experiments were conducted, a MOD-GENII system was equipped with a HD-25 Oxford Applied Research RF activated plasma source to provide active nitrogen, and elemental Ga was used as the group III-source. In all experiments arsenic was used in the form of As₂ produced by a Veeco arsenic-valved cracker. The MBE system was equipped with a reflection high energy electron diffraction (RHEED) facility (12 kV) for surface reconstruction analysis. For the growth of all GaNAs samples, the same active N flux (total N beam equivalent pressure (BEP) ˜1.5 10⁻⁵ Torr) was used and the same deposition time of 2 hours. In order to study the possibility of the growth of amorphous GaNAs alloys on low cost substrates, also used in other experiments were standard microscope glass slides (76 mm×26 mm×1 mm) and Pyrex glass as the substrate material.

Note that with MBE film growth the substrate temperature is normally measured using an optical pyrometer. However, because uncoated transparent sapphire or transparent glass was used in the experiments, estimates for the growth temperature were made based on the thermocouple readings (in mV).

The results are plotted in FIG. 3, the amount of Mg introduced during film growth a function of its partial pressure, and the resistivity of the thus produced film reported in Ohms-cm. As depicted in FIG. 3, the lowest resistivity was obtained at an Mg BEP of about 1×10⁻⁸ Torr. Films of higher, but still significantly reduced resistivities resulted at Mg partial pressures of between 3×10⁻⁹ to 3×10⁻⁸.

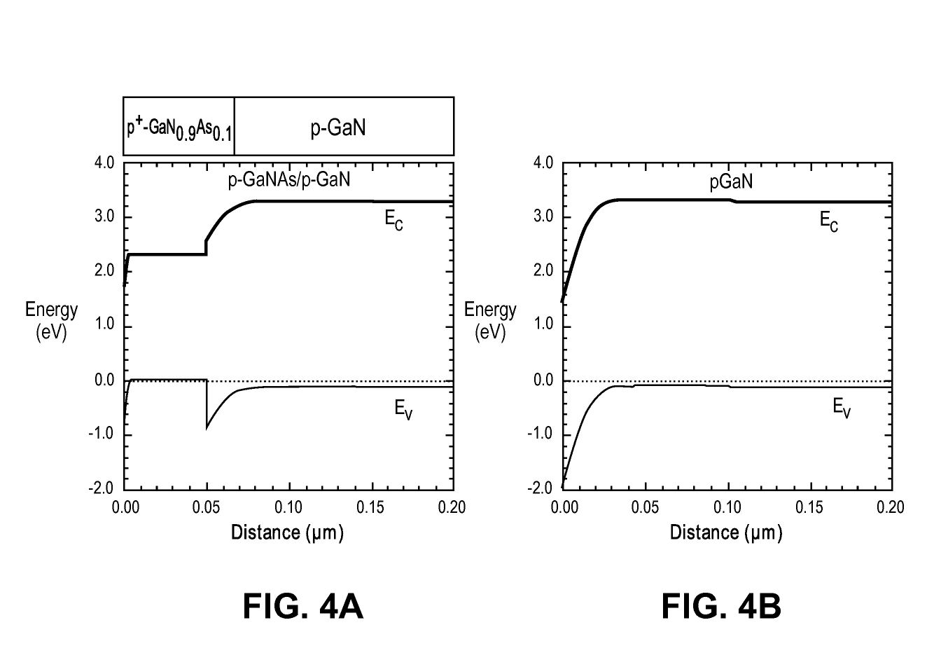

Next considered was the use of these Mg doped films as ohmic contacts for GaN, InGaN, AlGaN, AlGaInN layers, films commonly used in light emitting diodes, lasers and photovoltaic cells. FIG. 4A is a calculated energy band diagram for a 50 nm thick layer of p+-GaN_{0.9}As_{0.1} (where p is Mg and p˜1×10²⁰/cm³) formed upon a layer of p doped GaN (with hole concentration of p˜10¹⁸/cm³). FIG. 4B is a calculated energy band diagram for the same p GaN layer without the addition of the ohmic GaNAs:Mg contact layer of FIG. 4A. The calculations were performed using a one dimensional solar cell simulation program SCAPS [M. Burgelman et al. Thin Solid Films 361-362, 527 (2000).] The large carrier barrier of 2 eV (FIG. 4B) is reduced to <1 eV when a GaNAs:Mg layer is inserted between the metal and p-GaN layers. This barrier reduction serves to drastically reduce the contact resistance of the device.

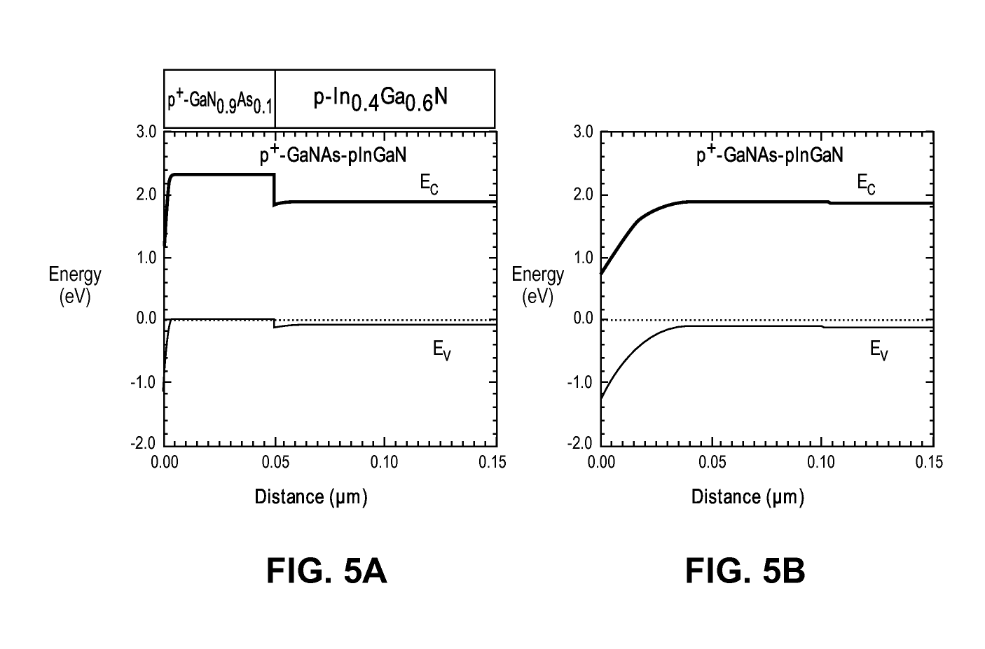

FIG. 5 is a similar calculated energy band diagram for an In_{0.4}Ga_{0.6}N layer (with a hole concentration of p˜10¹⁸/cm³) for both (A) with, and (B) without an applied p+-GaN_{0.9}As_{0.1} layer of about 0.05 μm thick. Similarly to the p+-GaN/pGaNAs combination, insertion of a thin GaNAs:Mg layer between the metal and the InGaN layer essentially eliminates the ˜1.1 eV barrier for carrier transport.

It is to be appreciated that the GaNAs:Mg doped alloy of this invention may be applied as a conformal layer over a p-doped photovoltaic layer or as a patterned film. In one embodiment the GaNAs:Mg doped layer may form the top layer of a device, such as in the case of a PV cell. As it is the first layer through which sunlight passes, necessarily it should be thin, preferably in the range of 10 to 30 nm. By patterning the layer, for a given thickness, even more of the sunlight can be allowed to pass unimpeded through the layer.

It is also to be appreciated that other Group V metals such as P, Sb, and Bi can be used in place of As, with similar improvements in ohmic performance expected. The layer should preferably be amorphous, which is a function of both composition (x=0.1 to 0.8) and MBE formation temperature (generally below 300° C., and preferably around 100° C.). Moreover the application of this material as an ohmic contact layer is not limited to GaN and Indium Gallium nitride alloys. It can also be used as the p-type ohmic contact layer when combined with an underlying layer such as Aluminum Gallium Nitride (AlGaN) and Aluminum Indium Gallium Nitride (AlInGaN).

For the low resistivities required or the ohmic contact layer, the film may be either crystalline or amorphous. However, it is preferable that this layer be amorphous, both because of the elimination of the need for lattice matching, as well as the flexibility inherent in the amorphous film, which when used in a photo voltaic cell, facilitates the use of flexible substrates, such as plastic, where film cracking is not an issue. For GaN₁₋ₓAsₓ films, to obtain the amorphous form, a high level of level of arsenic content is required. That is, where mole fraction x=0.1 to 0.8. In the case of MBE processing as described herein, it has been found that such high levels of arsenic doping are best achieved at low temperatures, such as at 300° C. and below.

Worthy of note, because the Mg is introduced into the reactor simultaneously during the GaNAs film forming process, it actually substitutes for gallium atoms. Thus, while the Ga, N, As and Mg are all alloyed together, by controlling the MBE parameters (such as temperature, and flux of the components), one is able to obtain Mg substitution for gallium, inserted of having the Mg randomly distributed at various locations throughout the GaNAs film.

As used herein, alloying refers to substitutions of isoelectronic species (group V element (As) with another group V element (N). Alloying does not affect electrical properties of the material. Also as used herein, doping refers to substitution with non-isoelectronic elements e.g. substitution of a group III element (Ga) with a group II element (Mg). The Mg atom needs the third electron to form a bond with the surrounding group V atoms. It takes this electron from the valence band leaving behind a hole (p-type doping).

In yet another embodiment of the invention, lightly doped GaNAs films, such as with Mg, can also serve as photovoltaic absorber layers in solar cell devices, As a PV layer, these films are grown to greater thicknesses, such as for example between 0.5 and 2 microns. Having recently overcome the miscibility gap of GaAs and GaN alloys using low temperature molecular beam epitaxy (MBE) growth methods, GaN₁₋ₓAsₓ has been synthesized over the whole comrn position range in both crystalline and amorphous form. See Molecular beam epitaxy of crystalline and amorphous GaN layers with high As content, S. V. Novikov, et al, Journal of Crystal Growth, 311 (2009) 3417-3422, and Highly Mismatched GaN₁₋ₓAₓ Alloys in the Whole, Composition Range, K. M. Yu et al., J. Appl. Phys. 106, 103709 (2009). As already noted, these alloys are amorphous when x is between ˜0.1 to ˜0.8, the amorphous films having a smooth morphology, homogeneous composition and sharp, well defined optical absorption edges. The bandgap energy varies in a broad energy range from ˜3.4 eV in GaN to ˜0.8 eV at x=˜0.85.

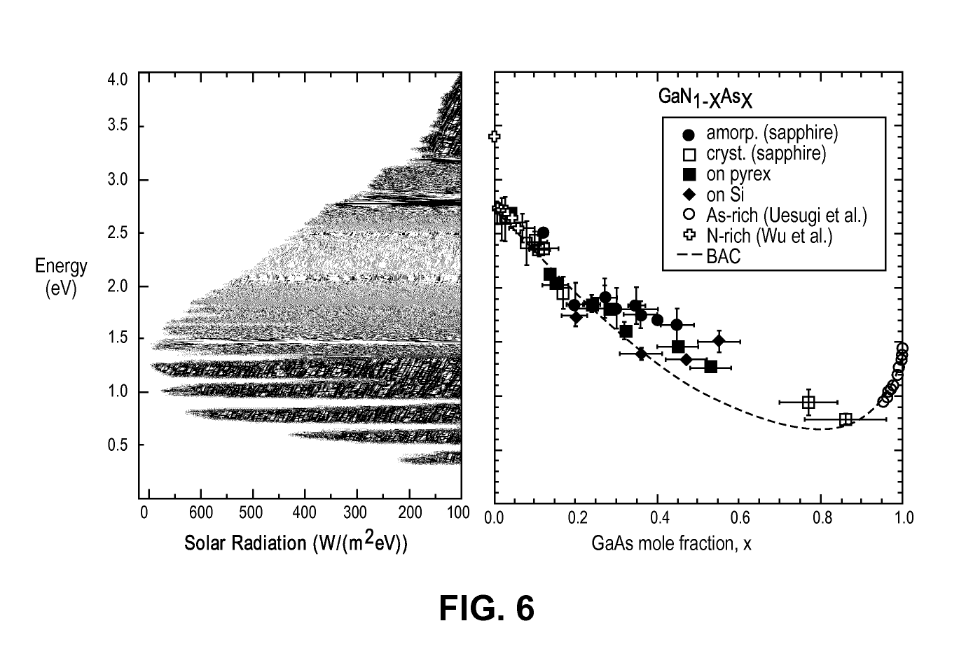

The large band gap range of amorphous GaNAs covers much of the solar spectrum (see FIG. 6), and therefore this material system can be used for full spectrum multi junction solar cells. The amorphous nature of the GaNAs alloys is particularly advantageous since no lattice matching is required between adjacent amorphous layers, and low cost substrates such as glass can be used for solar cell fabrication. The high absorption coefficient of ˜10⁵ cm⁻¹ for the amorphous GaN₁₋ₓAsₓ films suggests that only relatively thin films, on the order of 1 micron are necessary for photovoltaic application.

The GaNAs alloys of the invention, with their unique optical and electronic properties can be used to fabricate both single junction and multi junction cells. The solar cell performance can be easily optimized since the band gap of the alloy can be tuned by the composition of the material. It has been found that magnesium (Mg) and tellurium (Te) can be used for doping of the GaNAs alloy, to produce p-type and n-type alloys respectively. In the case of p-type doping, in principle, any group II material such as zinc, cadmium and the like may be used as the dopant. In the case of n-type doping, in principal, the Te can be substituted with any group IV type material such as carbon, tin, and the like, as well as any group VI type material such as oxygen, sulfur, selenium, etc.

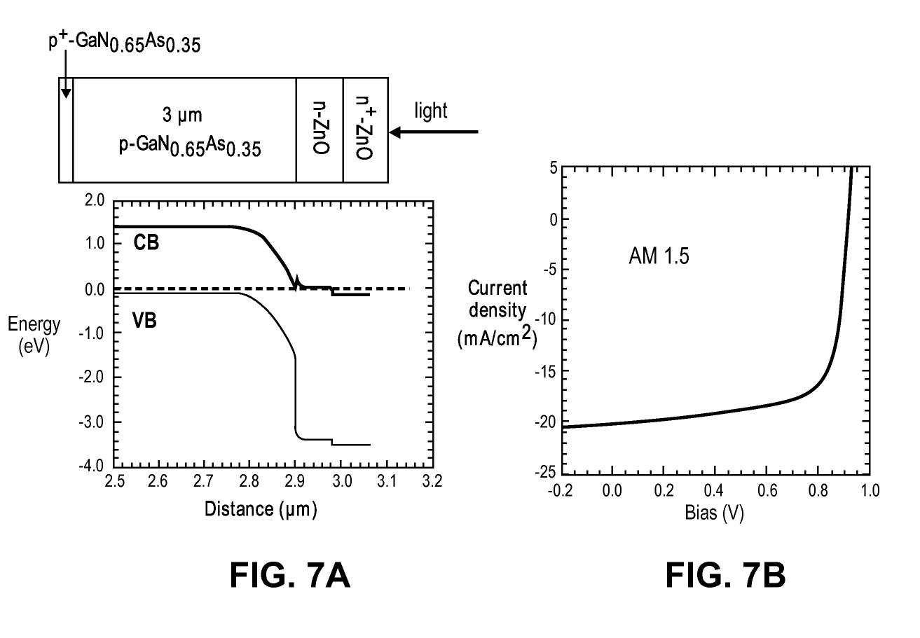

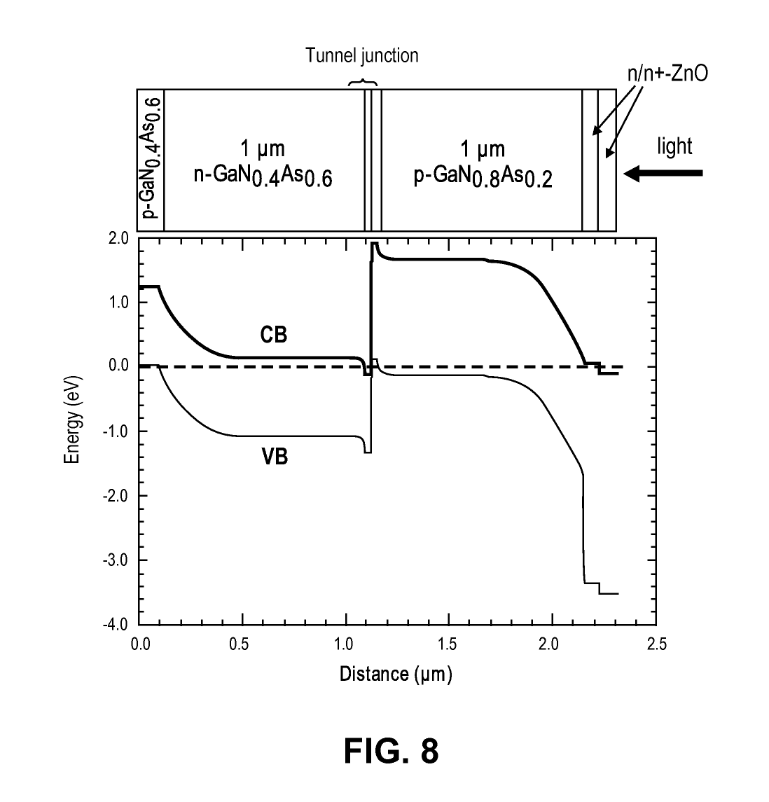

It has been found that the conduction band edge of the GaNAs alloy with an As composition of about 30% matches with that of ZnO, a commonly used window layer for thin film solar cells, and hence can be used as the n-type layer on a p-GaNAs layer in a GaNAs hetero-junction solar cell. The calculated energy band diagram of such a hetero junction structure is shown in FIG. 7A. The corresponding current voltage response under 1 sun AM 1.5 illumination is shown at FIG. 7B. Power conversion efficiency exceeding 14% can be expected using this structure. Furthermore, multi junction cells can be fabricated using this alloy system by adjusting the composition of the alloy in different layers. For example, at FIG. 8 the calculated energy band diagram is shown for a double junction structure using GaNAs alloys: a 20% As alloy top cell and 60% As alloy bottom cell. Such structure can be expected to yield maximum efficiencies of about 40%. In this case, the tunnel junction between the cells is composed of heavily n-type and p-type doped layers, which can be formed using the same MBE processes described above.

In summary, as illustrated in FIG. 7, a highly doped p-type GaNAs:Mg layer (the thin layer to the far left, adjacent the 3 μm GaN_{0.65}As_{0.35} layer) can be used as an ohmic contact to the absorber layer (the 3 μm GaN_{0.65}As_{0.35} layer adjacent the n-ZnO layer) in a single heterojunction solar cell as shown in FIG. 7. Similarly, highly conducting p and n-GaN As layers can be efficiently used as tunnel junction layers in a tandem cell configuration as shown in FIG. 8. To form the lightly p-type doped GaNAs layers for PV applications, one can use the same MBE equipment used for the formation of the p-doped ohmic contact layer, wherein the amount of Mg (or Te, as the case may be) that is introduced into the reaction chamber is restricted during film formation to achieve the lightly doped state. In the case of a p doped PV GaNAs layer, to form the ohmic contact layer, the film formation process can be continued using the same MBE reactor, wherein the flux of the Mg is increased, such that the GaNAs layer becomes heavily doped, the reaction continued for a time sufficient to form the thin contact layer. As used herein, the term lightly doped refers to a Mg dopant concentration of about 10¹⁷/cm³. The term heavily doped refers to an Mg dopant concentration of above 3×10²⁰ atoms/cm³, such as for example as high as 10²¹ atoms/cm³.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A composition of matter comprising the doped metal alloy GaN₁₋ₓAsₓ:M, wherein x, the mole faction, is 0<x<1.

2. The composition of matter wherein M comprises a Group II element.

3. The composition of matter of claim 2 wherein M is Mg.

4. The composition of matter of claim 1 wherein 0.1<x<0.8.

5. The composition of matter of claim 3 wherein Mg concentration is about 10²⁰ to 10²¹ atoms/cm³.

6. An ohmic contact film comprising the composition of claim 1 wherein the thickness of the film is between 0.005 and 0.05 μm.

7. The ohmic contact film of claim 6 wherein the film is amorphous.

8. An article of manufacture comprising the ohmic contact film of claim 7 wherein the ohmic contact film is applied to a p-type Group III nitride semiconductor film.

9. The article of manufacture of claim 8 wherein the ohmic contact film is applied as a conformal layer.

10. The article of manufacture of claim 8 wherein the ohmic contact film is applied as a patterned layer.

11. The article of manufacture of claim 8 wherein the p-type Group III nitride semiconductor film comprises p-doped GaN₁₋ₓAsₓ wherein 0.1<x<0.8.

12. The article of manufacture of claim 8 wherein the p-doped GaN₁₋ₓAsₓ film is lightly doped with Mg.

13. The article of manufacture of claim 11 wherein the p-doped GaN₁₋ₓAsₓ film is formed with other than As Group V dopant selected from the group comprising P, Sb, and Bi.

14. The article of manufacture of claim 11 wherein the thickness of Group III nitride semiconductor film is between 0.01 μm and 2 μm.

15. The article of manufacture of claim 11 wherein the thickness of the ohmic contact film is between 5 and 50 nm.

16. The article of manufacture of claim 11 wherein the p-doped GaNAs alloy is of the formula GaN_{0.65}As_{0.35}.

17. The ohmic contact film of claim 1 wherein M comprises Te.

18. An article of manufacture in which the n-doped film of claim 17 is applied to an n-doped Group III nitride semiconductor film.

19. The article of manufacture of claim 18 in which the n-doped Group III nitride semiconductor film comprises Te doped GaNAs.

20. A method of preparing the p-doped GaNAs film of claim 3 wherein the film is formed over a substrate, the film formation process carried out in a reaction chamber comprising the steps of:
placing elemental Ga, As and Mg in separate ovens, each of said ovens in fluid communication with said reaction chamber, wherein each of said ovens are brought to a specified temperature sufficient to volatilize the metal within;
cracking nitrogen gas into active and atomic nitrogen in a separate rf plasma chamber;
releasing, volatilized Ga, As, and Mg along with N into the reaction chamber, using shutters to control the simultaneous release of said elements, said reaction chamber maintained at temperatures below 300° C., and thereafter,
allowing the introduced materials to react at the surface of said substrate to form said p-doped GaNAs:Mg film overtop said substrate.
